(19) United States
(12) Patent Application Publication
(10) Pub. No.: US 2023/0043353 A1
(43) Pub. Date: Feb. 9, 2023

(54) MULTIPLE CAMERA APPARATUS FOR PHOTOLITHOGRAPHIC PROCESSING

(71) Applicant: Onto Innovation, Inc., Wilmington, MA (US)

(72) Inventors: Elvino DaSilveira, North Andover, MA (US); J. Casey Donaher, Westford, MA (US); Douglas A. Brown, Wilmington, MA (US)

(21) Appl. No.: 17/394,132

(22) Filed: Aug. 4, 2021

(51) Int. Cl. G03F 7/213; G03F 7/20

(52) U.S. Cl. CPC G03F 7/213; G03F 7/201

(57) ABSTRACT

Embodiments of a photolithographic machine with two or more camera systems (i.e., projection lens systems) are described herein. The photolithographic machine may include two or more cameras independently operated and controlled for exposing integrated circuit, flat panel display, and other substrates used in manufacturing semiconductor electronics. The cameras may be independently controlled to move laterally in the x-axis (i.e., not fixed). The independent control can include movement, focusing, tilt, reticle position, among other things.

### TECHNICAL FIELD

The present disclosure generally relates to photolithographic processing of integrated circuit and display substrates.

### BACKGROUND

Photolithography is used to fabricate patterns on a substrate, such as a silicon wafer or a flat panel display. Photolithography involves transferring a pattern from a photomask (or reticle) to a photosensitive surface on a substrate. Typically, photolithography is performed using a step-and-repeat or scanning process.

In these processes, the substrate is placed on a movable stage. A fixed camera is placed above the stage with the photomask of the pattern to be fabricated. The camera projects the pattern onto a portion of the substrate for fabrication. Then, the stage is moved along one axis (e.g., y-axis) and the process is repeated until a column of the patterns is fabricated on the substrate. Next, the stage is moved along the another axis (e.g., x-axis) and the process repeats to finish the next column. The process is repeated until all columns in the substrate are fabricated. These processes suffer from disadvantages such as low throughput, high cost, and low flexibility.

### BRIEF DESCRIPTION OF THE DRAWINGS

Various ones of the appended drawings merely illustrate example embodiments of the present disclosure and should not be considered as limiting its scope.

FIG. 1A illustrates example portions of a photolithography machine.

FIG. 1B illustrates a cross-section view of a photolithography machine.

FIG. 1C illustrates another cross-section view of a photolithography machine.

FIG. 2 illustrates a circuit block diagram of a photolithography machine.

FIG. 3 illustrates a flow diagram for a method for photolithographic processing using two or more movable cameras.

FIGS. 4A-4D illustrate a top view of the substrate being processed at different steps.

FIG. 5 illustrates a flow diagram for a method for photolithographic processing using two or more movable cameras.

FIG. 6 illustrates example portions of a photolithography machine,

FIG. 7 illustrates example portions of a photolithography machine.

### DETAILED DESCRIPTION

The present inventors recognized, among other things, a need for faster and more flexible photolithographic processing. Embodiments of a photolithographic machine with two or more camera systems i.e., projection lens systems) are described herein. The photolithographic machine may include two or more cameras independently operated and controlled for exposing integrated circuit, flat panel display, and other substrates used in manufacturing semiconductor electronics. The cameras may be independently controlled to move laterally in the x-axis (i.e., not fixed). Hence, the stage may move only in the y-axis, reducing the size and complexity of the stage area in the photolithographic machine. For example, a glass panel for displays can approximately be 1.5 meters by 1.8 meters; therefore, the size of the stage area of a photolithographic machine may be greatly reduced if the stage moves only in the y-axis (and not in the x-axis or limited movement in the x-axis).

The independently operated and controlled cameras enable multiple, independent image projections and concurrent exposures. The independent lateral movement of the cameras may allow for different configurations to be manufactured in the same run. For example, after fabricating columns in a first orientation (e.g., vertical along the y-axis), the cameras and the stage may be moved in such a way to fabricate on the same substrate in a second orientation (e.g., horizontal along the x-axis) to maximize the number of devices fabricated on the substrate sheet. In another example, different devices can be fabricated at the same time using the independent lateral movement of the cameras. One camera may be used to manufacture a smaller display (e.g., cell phone display) and the other camera may be used to manufacture a larger display (e.g., tablet display). Moreover, each camera may include independent tilting (or leveling) and focusing. Each camera may have its own set of sensors to align its photomask (or reticle) with the substrate plane to ensure that an optical axis of the camera is perpendicular to the substrate plane.

This document describes a photolithography machine including a stage to hold and move a substrate along a first axis. The photolithography machine also includes at least two projection cameras positioned opposite the stage to project images from respective image sources onto the substrate, each camera including at least one motor to laterally move the respective camera relative to the substrate independently along a second axis substantially perpendicular to the first axis.

This document also describes a method for fabricating onto a substrate. The method includes: positioning the substrate on a stage opposite at least two projection cameras at a first position; at the first position, projecting respective images from image sources onto the substrate using the at least two projection cameras; moving the stage along a first axis to a second position; at the second position, projecting respective images from the image sources onto the substrate using the at least two projection cameras; moving the at least two cameras independently along a second axis to a third position, the second axis being substantially perpendicular to the first axis; and at the third position, projecting respective images from the image sources onto the substrate using the at least two projection cameras.

This document further describes a lithography machine with a first and second projection camera systems. The first projection camera system includes a first reticle stage to hold a first photomask, a first projection lens, and a first motor to move the first projection camera along a x-axis. The second projection camera system includes a second reticle stage to hold a second photomask, a second projection lens, and a second motor to move the second projection camera along the x-axis independently of the first projection camera. The lithography machine also includes a stage positioned opposite the first and second projection cameras to carry a substrate along a y-axis.

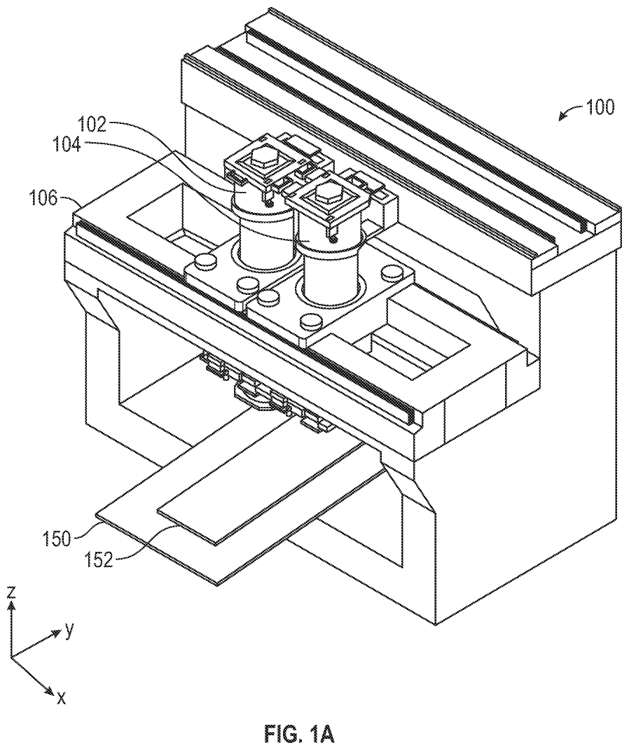

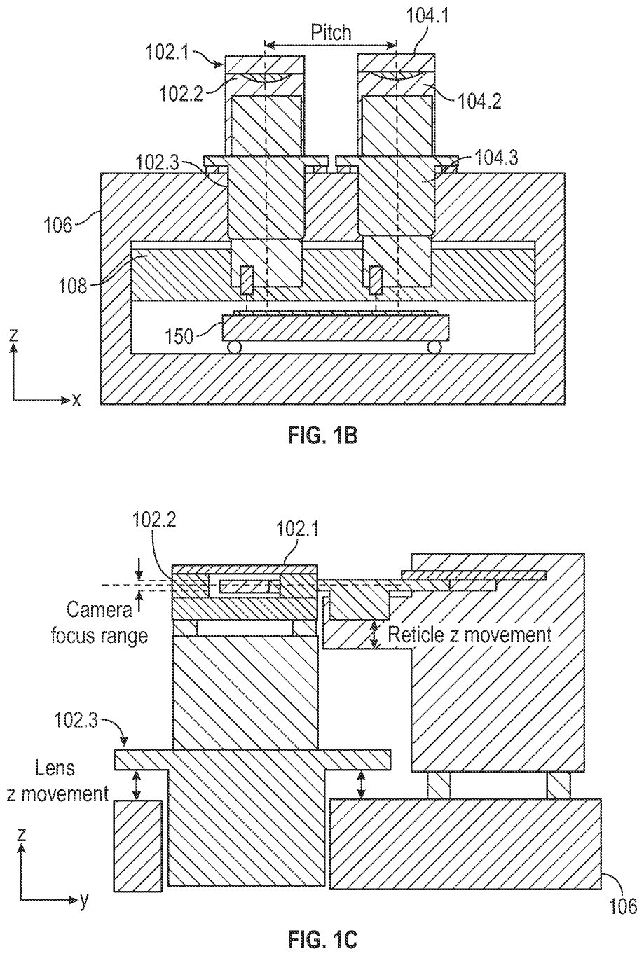

FIGS. 1A-1C illustrates example portions of a photolithography machine 100. The photolithography machine 100 may include two or more camera systems 102, 104, a bridge structure 106, a metrology frame. 1.08, and a stage 150 for carrying one or more substrates 152. The camera systems 102, 104 may be positioned on the bridge structure 106 above the stage 150, and each camera system 102, 104 may include one or more motors to allow independent movement in the x-axis, as described in further detail below. That is, each camera system 102, 1.04 may be controlled individually to move independently in the x-axis along the bridge structure 106. The bridge structure 106 may support the camera systems 102, 104 and may provide a precision guide for the movement of the camera systems 102, 104 along the x-axis. The bridge structure 106 may be provided as a granite structure.

Each camera system 102, 104 may include, among other things, an illuminator 102.1, 104.1; a reticle stage 102.2, 104.2; and a projection lens 1.02.3, 104.3. The camera systems 102, 104 may be configured to expose their respective patterns or images substantially at the same time (i.e., concurrently or simultaneously). The illuminator 102.1, 104.1 may include a light source to generate light on top of the reticles placed on the reticle stages 1.02.2, 1.04.2, respectively. The light source may be provided a UV LED (ultra-violet light emitting diode) system and associated optics.

The reticle stages 102.2, 104.2 may include alignment devices to align the reticles placed thereon relative to the stage 150. The alignment devices may include 6-axis reticle chuck, as described for example in USP 7,385,671, entitled “High Speed Lithography Machine and Method,” which is incorporated herein by reference in its entirety, including but not limited to those portions that specifically appear hereinafter, the incorporation by reference being made with the following exception: In the event that any portion of the above-referenced patent is inconsistent with this application, this application supersedes the above-referenced patent. Each axis of the 6-axis chuck may have built-in single-axis, coarse, velocity and position sensors. For example, FIG. 1C shows the reticle movement in the z-axis and the corresponding camera-focus range.

Each reticle stage 102.2, 1.04.2 is configured to hold a separate reticle (or photomask or image source) to allow for different pattern fabrication, as described in further detail below. The reticle stages 102.2, 104.2 may be aligned independently relative to the stage to account for different variations on the substrate or different pattern fabrication. Each camera 102, 104 may have its own set of sensors to align its photomask (or reticle) with the substrate plane to ensure that an optical axis of the camera is perpendicular to the substrate plane. For example, the sensors (e.g., six sensors) for each camera 102, 104 may use the metrology frame 108 as reference for proper alignment. The metrology frame 108 may be straight and rigid and therefore provide a reference for flatness, straightness, height, position, etc.

The projection lens 102.3, 104.3 may project the pattern or image on each of the reticles onto the substrate placed on the stage 150. The projection lens 102.3, 104.3 may include one or more optical lenses. The projection lens 102.3, 104.3 may include individual, real-time, auto focus sensors. The optical properties of the projection lens 102.3, 104.3 may be adjusted based on the auto-focus sensors to focus the projected pattern or image on the substrate as needed.

Each camera 102, 104 may include one or more X motors (or actuators) to move the cameras in the x-axis along the bridge structure 106. For example, each camera 102, 104 may include two linear X motors for moving the cameras in each direction along the x-axis. The X motors may adjust the separation distance between the cameras 102, 104 to match the exposure pitch of the substrate. Placement and power of the X motors may be set to minimize the perturbations to the camera caused by the movement of the cameras and to minimize the settle time. The motors may be placed substantially close to the center of gravity (CG) of each of the cameras 102, 104. Hence, the move force applied to the cameras 102, 104 may be applied to the CS of the cameras. In one example, the X motors may be placed substantially close to the CS of the projection lens 102.3, 104.3 and the move force may be applied to CS of the projection lens 102.3, 104.3.

Moreover, acceleration, jerk, and velocity of the motors may be kept low because the speed of the camera movement may not significantly impact the overall production time. A fabrication run can involve most of the steps in one axis (e.g., y-axis). For example, a fabrication run may contain 70 steps in along the y-axis, but only 5 steps along the x-axis. Therefore, the speed of the cameras in the x-axis may not have as large of an impact on the run time as the speed of the stage in the y-axis. Moreover, the cameras 102 and 104 may be moved in the x-axis concurrently with the stage in y-axis to further increase throughput.

Each camera 102, 104 may also include one or more Z motors (or actuators) to move the cameras in the z-axis for proper alignment. For example, each camera 102, 104 may include four Z actuators, which are preloaded against gravity. The Z actuators may provide vertical force arranged symmetrically about the CG of the cameras 102, 104 and for tip and tilt of the optical column in the cameras 102, 104. In one example, one of the Z actuators may be used for damping. The cameras 102, 104 may be constrained in the Y, θz, θx directions by air bearings referencing the vertical side of the bridge structure 106. For example, FIG. 1C shows the lens (camera) movement in the z-axis.

The stage 150 may be provided below the cameras 102, 104 and may carry one or more substrates during fabrication. The stage 150 may include a granite structure to hold the one or more substrates. The stage 150 may be movable in the y-axis using one or more y motors. In an embodiment, the stage may also allow limited travel in x-axis to allow for more flexibility in fabrication configurations, as described in further detail below.

Photolithography machine 100 is described above as including a projection system arranged vertically; however, other arrangements may also be used. For example, arrangements with components arranged vertically and horizontally using mirrors can also be used. such as those described in U.S. Pat. No. 7,385,671, entitled. “High Speed Lithography Machine and Method,” which again is incorporated herein by reference in its entirety.

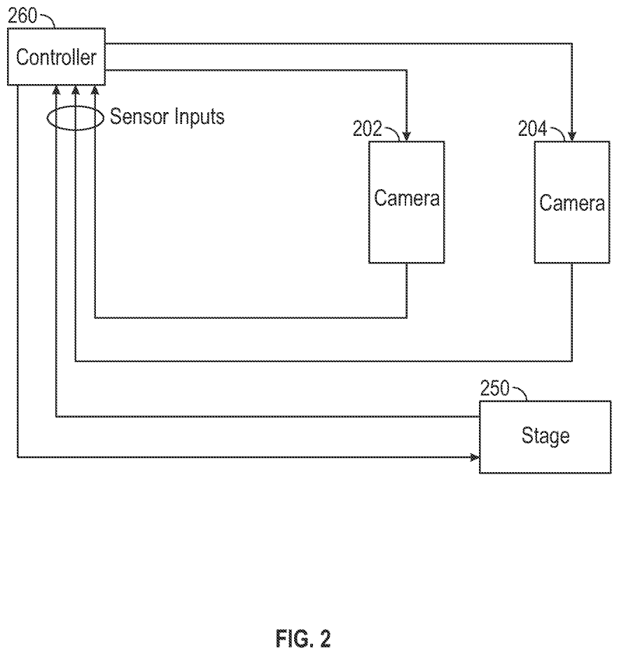

FIG. 2 illustrates a simplified circuit block diagram of a photolithography machine 200. The photolithography machine 200 may include two or more cameras 202, 204 and a stage 250, as described above with reference to FIG. 1. The photolithography machine 200 may also include a controller 260. The controller 260 may be provided as one or more computers, microcontrollers, microprocessors, or other suitable computing components. In one example, the controller 260 may be provided external to the photolithography machine 200.

The controller 260 may receive sensor inputs (as described above with reference to FIGS. 1A-1C) from the cameras 202, 204 and the stage 250. The controller 260 may also be programmed with the fabrication pattern for each camera 202, 204, which is stored in an associated memory. The controller 260 may control the independent lateral movement of the cameras 202, 204 in the x-axis. That is, the controller 260 may transmit a control signal to move camera 202 a first distance along the x-axis and may transmit another control signal to move camera 204 a second distance along the x-axis. The direction and length of the movements of the cameras may be independently controlled based on the fabrication layout. The controller 260 may also control the movement of the cameras 202, 204 in the z-axis and the movement of their respective reticle stages for alignment and focusing, as described above.

The controller 260 may also instruct the stage (and the substrate thereon) to be moved in the y-axis. In an embodiment, the controller 260 may also instruct the stage to be moved in the x-axis in a limited fashion to provide more flexibility in fabrication layouts. Techniques to control movement of the cameras and the stage are described in further detail below.

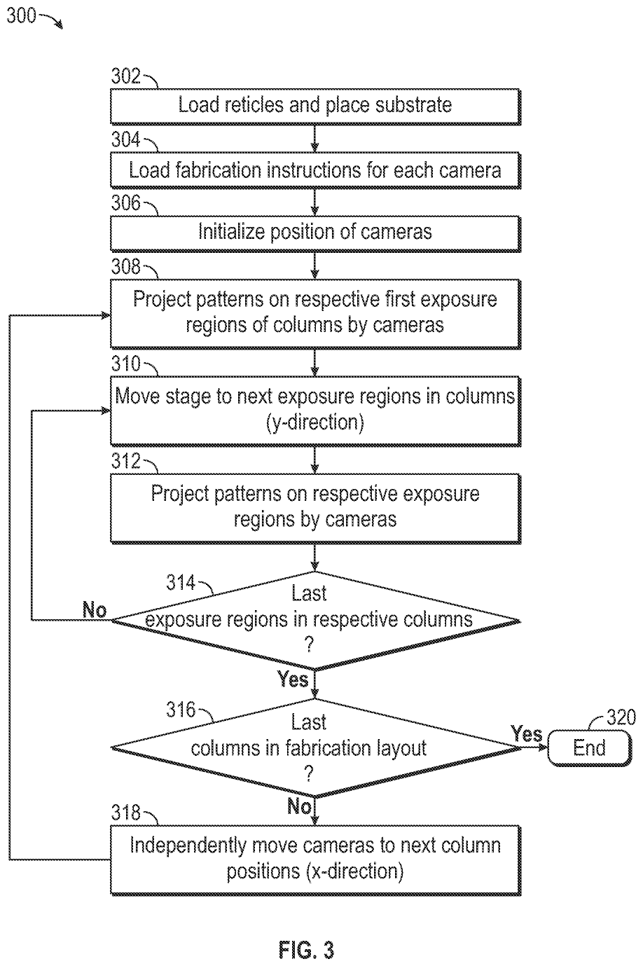

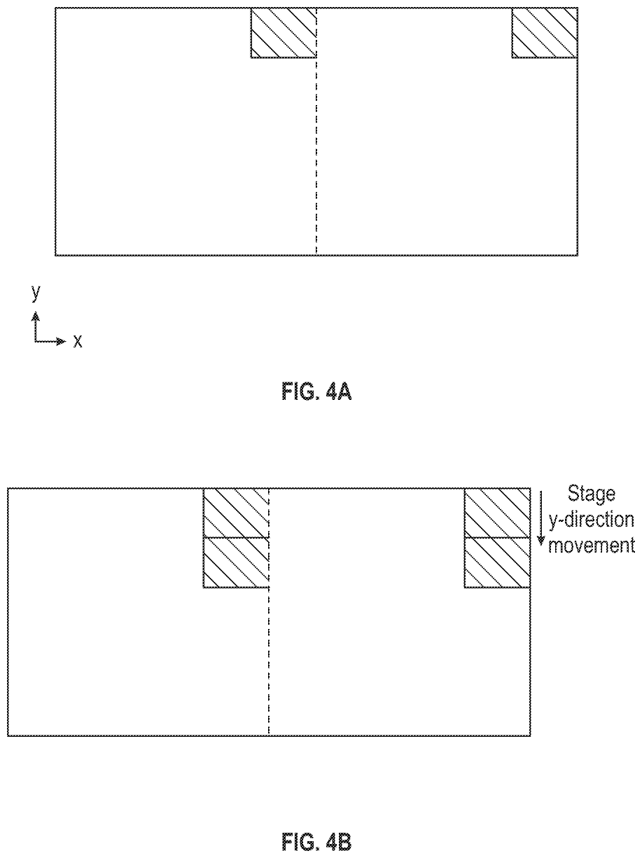

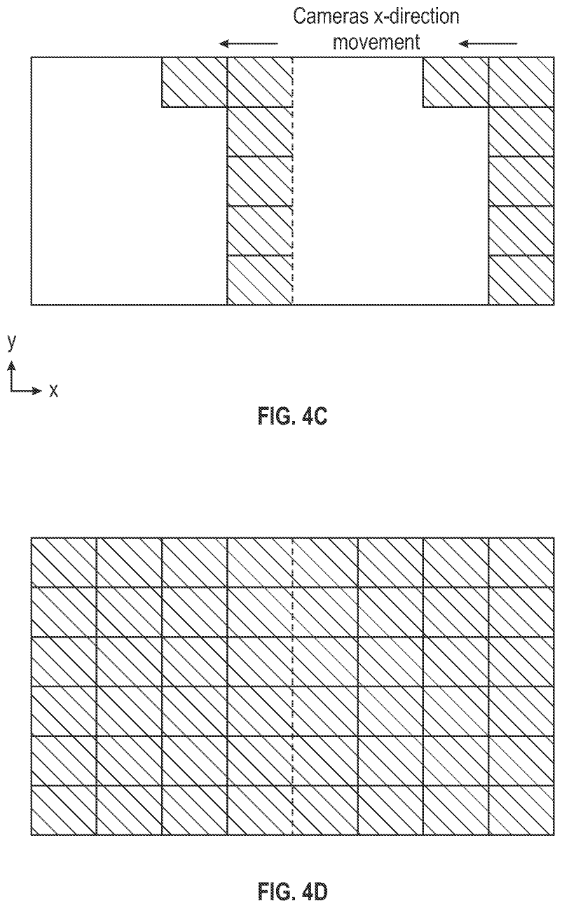

FIG. 3 illustrates a flow diagram for a method 300 for photolithographic processing using two or more movable cameras, and FIGS. 4A-4D illustrate a top view of the substrate being processed at different steps. For example, method 300 may be performed by the photolithographic machine described above with reference to FIGS. 1 and 2.

At 302, reticles (or photomasks) may be loaded into respective reticle stages of each of the cameras, and the substrate may be placed on the stage. The reticles may define the pattern to be projected onto the substrate(s) by each of the cameras. In an embodiment, the reticles for each of the cameras may be the same if the cameras are fabricating the same pattern. In another embodiment, the reticles for the cameras may include different patterns in situations where the cameras are fabricating different patterns in the same run.

At 304, instructions for fabricating the particular pattern(s) on the respective reticles may be retrieved and loaded. The instructions may include information such as fabrication layout, exposure time, size of each exposure region, pitch distance (distance between cameras), number of exposure regions in each column, number of columns, etc. Instructions regarding different reticle patterns may be pre-stored in a memory associated with a controller associated the photolithographic machine, and the instructions for the particular reticle(s) may be retrieved based on the loaded reticles.

At 306, the cameras may be initialized and may be moved. (if needed) so that the cameras are placed above their respective first exposure regions. FIG. 4A illustrates an example of an initial position of a two-camera system. Here, a first camera is positioned above a first exposure region in a first column located at an edge (e.g., right edge) of the substrate, and a second camera is positioned above its first exposure region in its first column located on the other side (e.g., left side) of a dividing line of the substrate. For example, the dividing line may be a center line of the substrate if each camera is configured to fabricate an equal area of the substrate. In another example, the dividing line may be off-center if one camera is configured to fabricate a larger area of the substrate as compared to the other camera. The camera separation may be set to match the exposure pitch of the substrate.

At 308, the first and second cameras may project images on their reticles on the respective exposure regions to fabricate the pattern on the images on the substrate in the respective regions at substantially the same time. Prior to projecting the images, the first and second cameras may align their respective reticle stages and/or projection lens with the substrate plane of the exposure region. Because of variations on the substrate and movement of the cameras, the substrate plane of the exposure region for the first camera may differ from the substrate plane of the exposure region for the second camera. Thus, each camera may perform independent tilting, leveling, and/or focusing. Each camera may utilize its own sensors to obtain position information regarding the substrate plane of its respective exposure region. Each camera may align its photomask (or reticle) with the substrate plane of its exposure region to ensure that an optical axis of the camera is perpendicular to the substrate plane prior to projecting the image.

At 310, the stage may be moved along the y-axis so that each camera is provided above the next exposure region in their respective column. FIG. 4B illustrates an example of the placement of the substrate and the cameras after the stage is moved. The cameras may not project light during the movement of the stage (or the cameras as discussed later below). For example, a shutter in each of the cameras may be closed.

At 312, the first and second cameras may project images on their reticles on the respective next exposure regions to fabricate the pattern on the images on the substrate in the respective regions. Again, prior to projecting the images, the first and second cameras may align their respective reticle stages and/or projection lens with the substrate plane of the exposure region, as described above with respect to step 308. Each camera may align its photomask (or reticle) with the substrate plane of its exposure region to ensure that an optical axis of the camera is perpendicular to the substrate plane prior to projecting the image.

At 314. A may be determined whether the previous exposure region was the last region in that particular column. If it is not the last exposure region in the particular column, steps 310-312 may be repeated until the last exposure region in the particular column has been fabricated.

At 316, after the last region in the column is fabricated, the cameras may be moved laterally in the x-axis so that the cameras are placed on top of the next column to be fabricated on the substrate. The distance of the lateral movement by the cameras may be set based on the fabrication instructions. In an example, the cameras and the stage may be moved concurrently in the x- and y-axis, respectively. FIG. 4C illustrates an example of the placement of the substrate and the cameras after the cameras are laterally moved. In this example, both cameras are moved the same distance. In another example, the cameras may be moved different distances along the x-axis for fabricating different size panels by each camera.

Next, steps 308-314 may be repeated to fabricate all exposure regions in the particular column. This process may be repeated until all columns for each camera are completed. (see step 318), FIG. 4D illustrates an example of a completed fabrication process. For product layouts with an odd number of total columns, one camera may be idle for one column.

As mentioned above, the independent control of the cameras may allow different configurations to be manufactured in the same run. For example, after a series of columns are fabricated in a vertical orientation using the multi-camera photolithographic machine as described herein (e.g., method 300 of FIG. 3), one or more columns may then be fabricated in a horizontal orientation to maximize substrate utilization. Here, the lateral movement of the cameras may allow more flexible control. Moreover, the stage may be moved in the x-axis in a limited fashion and/or rotated to allow for fabricating substrates in different configurations.

In another example, a multi-camera photolithographic machine as described herein may be used to fabricate products with different form factors in the same run. In a two-camera machine, a first camera may fabricate displays with a first form factor such as for a cell phone display, and simultaneously a second camera may fabricate displays with a second form factor such as for a tablet display. The independent movement of the cameras may allow the cameras to move different distances when starting a new column for fabrication. The first camera may move a smaller distance in the x-axis as compared to the second camera because the form factor for the cell phone display is smaller than the form factor for the table display. Thus, the pitch (distance between the cameras) may change during a run because the cameras are moving different distances.

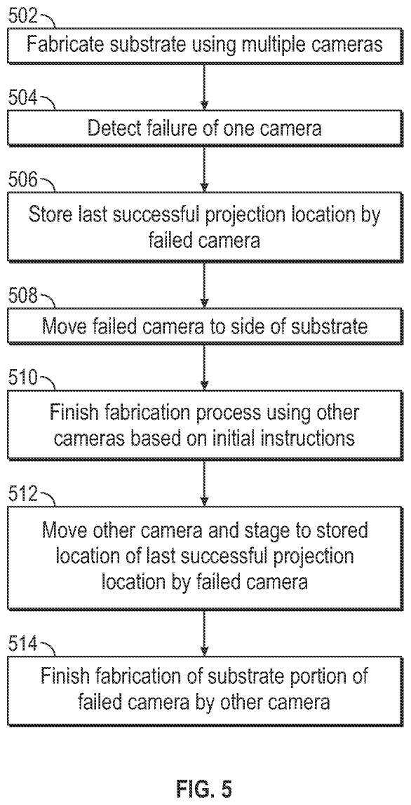

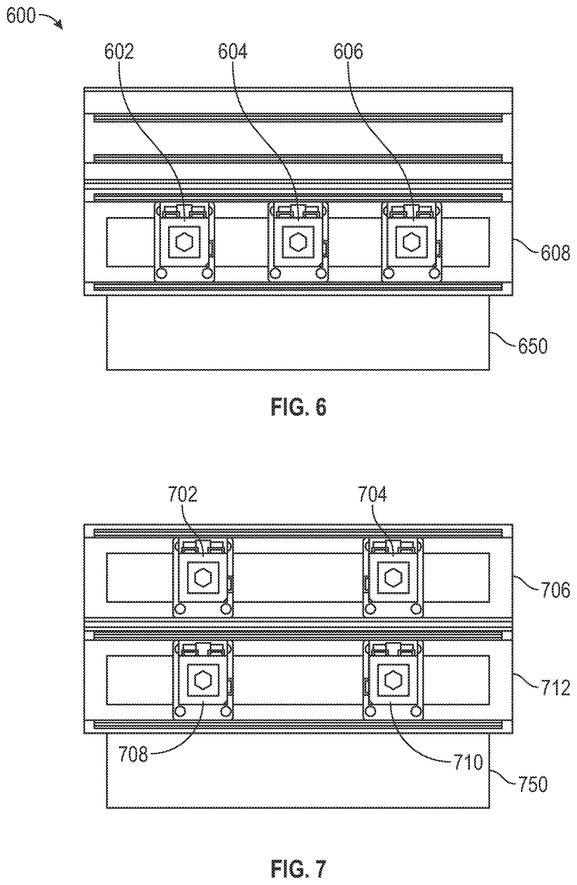

Moreover, the independent control of the cameras may increase reliability by providing redundancy. If one camera fails during a run, the other camera(s) may finish the run without having to stop the run or wasting the substrate panel. FIG. 5 illustrates a flow diagram for a method 500 for photolithographic processing using two or more movable cameras in the event of a failure of one of the cameras. At 502, the cameras may each be fabricating patterns on the substrate based on the corresponding instructions, as described for example with reference to FIG. 3. At 504, the machine may detect a failure event with one of the cameras.

At 506, the location of the last successful projection by the failed camera may be recorded and stored.

At 508, the failed camera may be moved along the x-axis to the side of the substrate. The other camera(s) may remain at their respective positions. In one example, the failed camera may remain at its position and move along with the cameras, but it does not project.

At 510, the other camera(s) may finish their fabrication process based on the initial instructions. In a two-camera system for example, the other camera may finish fabrication of its designated portion of the substrate panel, as described above with reference to FIGS. 3 and 4.

At 512, the other camera(s) may be moved laterally in the x-axis and the stage may be moved in the y-axis, if needed, based on the stored last successful projection location by the failed camera. For example, the other camera(s) may be moved to the next region after the last successful projection location on the fabrication layout.

At 514, the other camera(s) may complete the fabrication of the portion originally designated for the failed camera. In a two-camera system for example, the other camera may be moved to next location after the last successful projection by the failed camera, and that camera may then finish the fabrication of the substrate panel.

As mentioned above, a photolithography machine may include more than two cameras as described herein. FIG. 3 illustrates example portions of a photolithography machine 600 with three cameras. The photolithography machine 600 may include three cameras 602, 604, 606 arranged in a row; the cameras may be provided as described herein. The photolithography machine 600 may also include a bridge structure 608 to support the cameras 602, 604, 606. The cameras 602, 604, 606 may be positioned opposite (e.g., above) a stage 650, as described herein.

FIG. 7 illustrates example portions of a photolithography machine 700 with four cameras. The photolithography machine 700 may include four cameras 702, 704, 708, 710 arranged in two rows; the cameras may be provided as described herein The first set of cameras 702, 704 may be supported by a first bridge structure 706, and the second set of cameras 708, 710 may be supported by a second bridge structure 712. The cameras 702, 704, 708, 710 may be positioned opposite (e.g., above) a stage 750, as described herein.

In another example, a photolithography machine with six cameras, as described herein, may be provided. For example, the machine may include two rows with three cameras in each row.

### Various Notes

Each of the non-limiting aspects above can stand on its own or can be combined in various permutations or combinations with one or more of the other aspects or other subject matter described in this document.

The above detailed description includes references to the accompanying drawings, which form a part of the detailed description. The drawings show, by way of illustration, specific implementations in which the invention can be practiced. These implementations are also referred to generally as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other implementations can be used, such as by one of ordinary skill in the art upon reviewing the above description. The Abstract is provided to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed implementation. Thus, the following claims are hereby incorporated into the Detailed Description as examples or implementations, with each claim standing on its own as a separate implementation, and it is contemplated that such implementations can be combined with each other in various combinations or permutations. The scope of the invention should be determined with reference to the appended claims, along with the full scope of equivalents to which such claims are entitled.

What is claimed is:

1. A photolithography machine, comprising:
a stage to hold and move a substrate along a first axis; and
at least two projection cameras positioned opposite the stage to project images from respective image sources onto the substrate, each camera including at least one motor to laterally move the respective camera relative to the substrate independently along a second axis substantially perpendicular to the first axis.

2. The photolithography machine of claim 1, wherein the at least one motor is positioned to apply a force at a substantially center of gravity of the respective camera.

3. The photolithography machine of claim 1, wherein the at least one motor is positioned to apply a force at substantially a center of gravity of a projection lens system of the camera.

4. The photolithography machine of claim 1, wherein each camera includes two motors to move the respective camera independently in two directions along the second axis.

5. The photolithography machine of claim 1, further comprising:
a controller to control movement of the at least two projection cameras and the stage based on a fabrication layout of the substrate.

6. The photolithography machine of claim 1, further comprising:
a controller to receive sensor inputs regarding placements of the at least two projection cameras relative to the substrate and to control independent movement of the at least two projection cameras along a third axis substantially perpendicular to the first and second axes.

7. The photolithography machine of claim 6, wherein the controller is configured to independently focus each camera.

8. The photolithography machine of claim 6, wherein the controller is configured to independently move a reticle stage of each camera to align the reticle stage of each camera with respective portions of the substrate opposite each camera.

9. The photolithography machine of claim 1, further comprising:
a bridge structure to support the at least two projection cameras and to provide a guide for movement of the cameras along the second axis.

10. The photolithography machine of claim 1, further comprising:
a metrology frame to provide a reference for aligning the at least two projection cameras with the substrate.

11. A method for fabricating onto a substrate, the method comprising:
positioning the substrate on a stage opposite at least two projection cameras at a first position;
at the first position, projecting respective images from image sources onto the substrate using the at least two projection cameras;
moving the stage along a first axis to a second position;
at the second position, projecting respective images from the image sources onto the substrate using the at least two projection cameras;
moving the at least two cameras independently along a second axis to a third position, the second axis being substantially perpendicular to the first axis; and
at the third position, projecting respective images from the image sources onto the substrate using the at least two projection cameras.

12. The method of claim 11, further comprising:
for each camera, applying a force at substantially a center of gravity of the respective camera.

13. The method of claim 11, further comprising:
for each camera, applying a force at substantially a center of gravity of a projection lens system of the respective camera.

14. The method of claim 11, further comprising:
receiving a plurality of sensor inputs;
based on the sensor inputs, adjusting each of the cameras independently to align a reticle stage of each camera with respective portions of the substrate opposite each camera.

15. The method of claim 11, further comprising:
detecting a failure event of a first camera of the pair of cameras;
storing location of last projection by the first camera of a first designated portion of the substrate;
complete fabrication of a second designated portion of the substrate by the second camera;
after completion of the second designated portion, moving the second camera based on the stored location of the last successful projection by the first camera; and
complete fabrication of the first designated portion of the substrate by the second camera.

17. The method of claim 11, wherein the at least two cameras and the stage are moved substantially concurrently.

18. A lithography machine, comprising:
a first projection camera system comprising
a first reticle stage to hold a first photomask,
a first projection lens, and
a first motor to move the first projection camera along a x-axis;
a second projection camera system comprising
a second reticle stage to hold a second photomask,
a second projection lens, and
a second motor to move the second projection camera along the x-axis independently of the first projection camera; and
a stage positioned opposite the first and second projection cameras to carry a substrate along a y-axis.

19. The lithography machine of claim 18, wherein the first and second motors are positioned to apply a first and second force substantially at a center of gravity of the first and second cameras, respectively.

20. The lithography machine of claim 18, wherein the first and second motors are positioned to apply a first and second force substantially at a center of gravity of the first and projection lens, respectively.
